(19) United States
(12) Patent Application Publication
(10) Pub. No.: US 2022/0140574 A1
(43) Pub. Date: May 5, 2022

(54) HELICAL EMITTER STACKING FOR WAVELENGTH-BEAM-COMBINING LASER SYSTEMS

(71) Applicant: Panasonic Intellectual Property Management Co, Ltd, Osaka (JP)

(72) Inventors: Wang-Long ZHOU, Revere, MA (US); Michael DEUTSCH, Derry, NH (US); Francisco VILLARREAL-SAUCEDO, Middleton, MA (US); Bien CHANN, Merrimack, NH (US); Krzysztof Michal NOWAK, Andover, MA (US); Jesus Fernando MONJARDIN LOPEZ, Pelham, NH (US)

(21) Appl. No.: 17/514,130

(22) Filed: Oct. 29, 2021

Related U.S. Application Data
(60) Provisional application No. 63/109,463, filed on Nov. 4, 2020.

(51) Int. Cl. H01S 5/42; H01S 5/00; H01S 5/40; G02B 6/32

(52) U.S. Cl. CPC H01S 5/426; H01S 5/005; H01L 25/0756; G02B 6/32; H01S 5/4087

(57) ABSTRACT

In various embodiments, multiple laser emitters are helically arranged around a central axis and emit their individual beams toward the central axis. A collection of mirrors is disposed at the central axis, and each mirror is angled so that the reflected beams all exit the helical stack, in parallel and vertically stacked, in the same direction toward a shared exit point.

### RELATED APPLICATIONS

This application claims the benefit of and priority to U.S. Provisional Patent Application No. 63/109,463, filed Nov. 4, 2020, the entire disclosure of which is hereby incorporated herein by reference.

### TECHNICAL FIELD

In various embodiments, the present invention relates to laser systems, specifically laser systems featuring beam emitters that are helically stacked.

### BACKGROUND

High-power laser systems are utilized for a host of different applications, such as welding, cutting, drilling, and materials processing. Such laser systems typically include a laser emitter, the laser light from which is coupled into an optical fiber (or simply a “fiber”), and an optical system that focuses the laser light from the fiber onto the workpiece to be processed. Optical systems for laser systems are typically engineered to produce the highest-quality laser beam, or, equivalently, the beam with the lowest beam parameter product (BPP). The BPP is the product of the laser beam's divergence angle (half-angle) and the radius of the beam at its narrowest point (i.e., the beam waist, the minimum spot size). That is, BPP=NA×D/2, where D is the focusing spot (the waist) diameter and NA is the numerical aperture; thus, the BPP may be varied by varying NA and/or D. The BPP quantifies the quality of the laser beam and how well it can be focused to a small spot, and is typically expressed in units of millimeter-milliradians (mm-mrad). A Gaussian beam has the lowest possible BPP, given by the wavelength of the laser light divided by pi. The ratio of the BPP of an actual beam to that of an ideal Gaussian beam at the same wavelength is denoted M², which is a wavelength-independent measure of beam quality.

Wavelength beam combining (WBC) is a technique for scaling the output power and brightness from laser diodes, laser diode bars, stacks of diode bars, or other lasers arranged in a one- or two-dimensional array. WBC methods have been developed to combine beams along one or both dimensions of an array of emitters. Typical WBC systems include a plurality of emitters, such as one or more diode bars, that are combined using a dispersive element to form a multi-wavelength beam. Each emitter in the WBC system individually resonates, and is stabilized through wavelength-specific feedback from a common partially reflecting output coupler that is filtered by the dispersive element along a beam-combining dimension. Exemplary WBC systems are detailed in U.S. Pat. No. 6,192,062, filed on Feb. 4, 2000, U.S. Pat. No. 6,208,679, filed on Sep. 8, 1998, U.S. Pat. No. 8,670,180, filed on Aug. 25, 2011, and U.S. Pat. No. 8,559,107, filed on Mar. 7, 2011, the entire disclosure of each of which is incorporated by reference herein.

In order to maximize output power, many WBC systems combine beams emitted by multiple-beam emitters, such as diode bars. (As used herein, a “multiple-beam emitter” includes multiple beam sources, each emitting a beam, within a single package. A diode bar, in which each beam source is a semiconductor diode, is one example.) That is, in such systems multiple beams emitted by each of multiple diode bars are combined into a single output beam. Diode bars conveniently provide multiple, closely spaced, emitters (e.g., 19-49, or even more) within a single package. However, various issues may arise related to the use of diode bars in WBC systems.

In a diode bar, individual diode emitters are situated side-by-side in the slow-axis direction of the emitted beams. However, when such beams are combined into a single beam in WBC systems, it is generally preferred to do so in the fast-axis dimension for enhanced beam quality (for example, beam combining in the slow-axis dimension may result in pointing or alignment errors that may compromise the quality of the combined beam). Thus, in WBC systems, diode bars are often utilized with beam rotators (or “optical twisters”) that optically rotate the beams by 90° to thereby facilitate beam combining in the fast-axis dimension. However, optical beam rotators constitute additional expense in WBC systems, and their use may even result in power loss and optical aberrations that compromise beam quality.

Moreover, multiple-beam emitters such as diode bars often suffer from “smile,” i.e., misalignment or curvature in the horizontal, slow-axis dimension. Even if smile is not inherently present in a bare diode bar, it may be induced in the diode bar when installed in the laser system, due to, for example, unbalanced stresses induced by physical (e.g., mounting) and/or thermal effects. Diode bars also typically require high operating currents to drive the multiple diode emitters, and can suffer from emitter-to-emitter thermal crosstalk within the bar, rendering cooling schemes more complicated and difficult.

In view of the above, there is a need for improved WBC laser sources and systems that address issues arising from the use of diode bars while still enabling the formation of high-quality output beams resulting from the combination of many input beams.

### SUMMARY

Various embodiments of the present invention provide laser beam sources for WBC systems based on arrangements of single emitters, i.e., individual packages each containing only a single beam source, such as semiconductor diode emitters. In various embodiments, the emitters are arranged such that their beams are optically stacked (e.g., in the fast-axis dimension) into an aligned beam stack, and such beam stacks may be conveniently utilized as inputs in WBC laser systems. As utilized herein, “stacked” beams propagate in the same direction and may be, but need not be, overlapping. While stacked beams are aligned with each other in at least one dimension (e.g., as viewed in plan or top view), in a perpendicular dimension (e.g., as viewed from the side) the beams typically do not fully overlap and may even be spatially separated from each other.

In various embodiments, the emitters are arranged such that they share a single SAC lens, and also such that the optical path lengths between each emitter and the SAC lens are substantially identical. In this manner, embodiments of the invention not only reduce overall system costs and increase system compactness (e.g., due to the use of a single SAC lens instead of dedicated SAC lenses for each emitter) and provide excellent beam quality due to the equal path lengths of the beams.

In various embodiments, the beams from the beam emitters (e.g., diode emitters) are stacked in the fast axis, obviating the need for beam twisters and the costs and beam-quality and power degradation concomitant therewith. Moreover, the use of single emitters enables the use of dramatically reduced operating currents, because single emitters may be conveniently electrically connected in series (in contrast, a diode bar is effectively multiple diode sources connected in parallel in a single package). Single emitters also do not suffer from emitter smile, resulting in higher-quality WBC output. The use of single emitters also minimizes the amount of thermal crosstalk between emitters, which helps simplify cooling design for the source emitters. Finally, single emitters such as diode emitters also have much longer lifetimes when compared to diode bars, which results in greater system operating time and less maintenance downtime and cost.

In various embodiments of the invention, multiple single-source emitters are helically arranged, i.e., spaced vertically and horizontally, around a central axis, and emit their individual beams toward the central axis. A collection of interleaving mirrors is disposed at the central axis, and each mirror is angled so that the reflected beams all exit the helical stack, in parallel and vertically stacked, in the same direction (i.e., toward a single point). In various embodiments, as viewed in plan or top view, the arranged emitters form one or more arcs of a circle. Typically, the emitter arrangement does not form a full circle in order to provide a gap for the emitted stacked beams to propagate away from the arrangement. Various embodiments of the invention feature a single shared SAC lens at the exit point for the beams, in order to collimate the stacked beams in the slow axis. In various embodiments, when viewed in plan view, the emitter arrangement includes a gap opposite the exit point, and in various embodiments another single emitter may emit its beam from that gap, through the center point without the need for reflection (i.e., without encountering an interleaving mirror), directly to the exit point and the SAC lens (if present). In various embodiments, the beam from this emitter may be utilized as an alignment reference for the other beams (i.e., as an alignment aid when the interleaving mirrors for the other emitters are arranged).

Herein, “optical elements” may refer to any of lenses, mirrors, prisms, gratings, and the like, which redirect, reflect, bend, or in any other manner optically manipulate electromagnetic radiation, unless otherwise indicated. Herein, it is understood that references to different “wavelengths” encompass different “ranges of wavelengths,” and the wavelength (or color) of a laser corresponds to the primary wavelength thereof; that is, emitters may emit light having a finite band of wavelengths that includes (and may be centered on) the primary wavelength.

Although diffraction gratings are utilized herein as exemplary dispersive elements, embodiments of the invention may utilize other dispersive elements such as, for example, dispersive prisms, transmission gratings, or Echelle gratings. Embodiments of the invention may utilize one or more prisms in addition to one or more diffraction gratings, for example as described in U.S. patent application Ser. No. 15/410,277, filed on Jan. 19, 2017, the entire disclosure of which is incorporated by reference herein.

In various embodiments, the stacked output beams from multiple such helical source modules may be combined into a single output beam (which may be a multi-wavelength beam) in a WBC system, via a dispersive element and a partially reflective output coupler. Such output beams may be coupled into optical fibers and/or utilized for processing of a variety of different workpieces. For example, embodiments of the present invention may couple one or more laser beams into an optical fiber. In various embodiments, the optical fiber has multiple cladding layers surrounding a single core, multiple discrete core regions (or “cores”) within a single cladding layer, or multiple cores surrounded by multiple cladding layers.

Laser systems in accordance with embodiments of the present invention may be utilized to process a workpiece such that the surface of the workpiece is physically altered and/or such that a feature is formed on or within the surface, in contrast with optical techniques that merely probe a surface with light (e.g., reflectivity measurements). Exemplary processes in accordance with embodiments of the invention include cutting, welding, drilling, and soldering. Various embodiments of the invention also process workpieces at one or more spots or along a one-dimensional processing path, rather than simultaneously flooding all or substantially all of the workpiece surface with radiation from the laser beam. In general, processing paths may be curvilinear or linear, and “linear” processing paths may feature one or more directional changes, i.e., linear processing paths may be composed of two or more substantially straight segments that are not necessarily parallel to each other.

Various embodiments of the invention may be utilized with laser systems featuring techniques for varying BPP of their output laser beams, such as those described in U.S. patent application Ser. No. 14/632,283, filed on Feb. 26, 2015, and U.S. patent application Ser. No. 15/188,076, filed on Jun. 21, 2016, the entire disclosure of each of which is incorporated herein by reference.

Laser systems in accordance with various embodiments of the present invention may also include a delivery mechanism that directs the laser output onto the workpiece while causing relative movement between the output and the workpiece. For example, the delivery mechanism may include, consist essentially of, or consist of a laser head for directing and/or focusing the output toward the workpiece. The laser head may itself be movable and/or rotatable relative to the workpiece, and/or the delivery mechanism may include a movable gantry or other platform for the workpiece to enable movement of the workpiece relative to the output, which may be fixed in place.

In various embodiments of the present invention, the laser beams utilized for processing of various workpieces may be delivered to the workpiece via one or more optical fibers (or “delivery fibers”). Embodiments of the invention may incorporate optical fibers having many different internal configurations and geometries. Such optical fibers may have one or more core regions and one or more cladding regions. For example, the optical fiber may include, consist essentially of, or consist of a central core region and an annular core region separated by an inner cladding layer. One or more outer cladding layers may be disposed around the annular core region. Embodiments of the invention may be utilized with and/or incorporate optical fibers having configurations described in U.S. patent application Ser. No. 15/479,745, filed on Apr. 5, 2017, U.S. patent application Ser. No. 15/879,500, filed on Jan. 25, 2018, and U.S. patent application Ser. No. 16/675,655, filed on Nov. 6, 2019, the entire disclosure of each of which is incorporated by reference herein.

Structurally, optical fibers in accordance with embodiments of the invention may include one or more layers of high and/or low refractive index beyond (i.e., outside of) an exterior cladding without altering the principles of the present invention. Various ones of these additional layers may also be termed claddings or coatings, and may not guide light. Optical fibers may also include one or more cores in addition to those specifically mentioned. Such variants are within the scope of the present invention. Various embodiments of the invention do not incorporate mode strippers in or on the optical fiber structure. Similarly, the various layers of optical fibers in accordance with embodiments of the invention are continuous along the entire length of the fiber and do not contain holes, photonic-crystal structures, breaks, gaps, or other discontinuities therein.

Optical fibers in accordance with the invention may be multi-mode fibers and therefore support multiple modes therein (e.g., more than three, more than ten, more than 20, more than 50, or more than 100 modes). In addition, optical fibers in accordance with the invention are generally passive fibers, i.e., are not doped with active dopants (e.g., erbium, ytterbium, thulium, neodymium, dysprosium, praseodymium, holmium, or other rare-earth metals) as are typically utilized for pumped fiber lasers and amplifiers. Rather, dopants utilized to select desired refractive indices in various layers of fibers in accordance with the present invention are generally passive dopants that are not excited by laser light, e.g., fluorine, titanium, germanium, and/or boron. Thus, optical fibers, and the various core and cladding layers thereof in accordance with various embodiments of the invention may include, consist essentially of, or consist of glass, such as substantially pure fused silica and/or fused silica, and may be doped with fluorine, titanium, germanium, and/or boron. Obtaining a desired refractive index for a particular layer or region of an optical fiber in accordance with embodiments of the invention may be accomplished (by techniques such as doping) by one of skill in the art without undue experimentation. Relatedly, optical fibers in accordance with embodiments of the invention may not incorporate reflectors or partial reflectors (e.g., grating such as Bragg gratings) therein or thereon. Fibers in accordance with embodiments of the invention are typically not pumped with pump light configured to generate laser light of a different wavelength. Rather, fibers in accordance with embodiments of the invention merely propagate light along their lengths without changing its wavelength. Optical fibers utilized in various embodiments of the invention may feature an optional external polymeric protective coating or sheath disposed around the more fragile glass or fused silica fiber itself.

In addition, systems and techniques in accordance with embodiments of the present invention are typically utilized for materials processing (e.g., cutting, drilling, etc.), rather than for applications such as optical communication or optical data transmission. Thus, laser beams, which may be coupled into fibers in accordance with embodiments of the invention, may have wavelengths different from the 1.3 μm or 1.5 μm utilized for optical communication. In fact, fibers utilized in accordance with embodiments of the present invention may exhibit dispersion at one or more (or even all) wavelengths in the range of approximately 1260 nm to approximately 1675 nm utilized for optical communication.

In an aspect, embodiments of the invention feature a laser apparatus that includes, consists essentially of, or consists of a plurality of emitters arranged to partially surround a central axis and positioned to each emit its beam to the central axis and, disposed at the central axis, a plurality of interleaving mirrors. The emitters may be single-beam emitters each configured to emit only a single beam, or one or more of the emitters may be multiple-beam emitters configured to emit two or more beams. Each of the interleaving mirrors is configured to receive the beam(s) from a different emitter and direct the beam(s) to a shared exit point, whereby a beam stack is output at the shared exit point. The emitters may be positioned such that optical distances traversed by each beam from its emitter to the shared exit point are all equal to each other.

Embodiments of the invention may include one or more of the following in any of a variety of combinations. Each emitter may include, consist essentially of, or consist of a diode emitter. The apparatus may include a plurality of fast-axis collimation (FAC) lenses. Each FAC lens may be positioned to receive the beam from a different emitter and collimate the beam in the fast axis. The apparatus may include a slow-axis collimation (SAC) lens disposed at the shared exit point and configured to receive, and collimate in the slow axis, the beam stack. When viewed in plan view, the emitters may be arranged in one or more circular arcs disposed around the central axis. Within each circular arc, the emitters may be positioned to form a single spiral staircase in which vertical heights of adjacent emitters increase along a length of the spiral staircase. The one or more circular arcs may include, consist essentially of, or consist of a first circular arc and a second circular arc. Vertical heights of emitters within the second circular arc may all be higher than vertical heights of emitters within the first circular arc. The emitters within the first circular arc may be vertically interleaved with the emitters within the second circular arc, whereby vertical heights of some emitters within the first circular arc are higher than vertical heights of some emitters within the second circular arc, and vice versa.

The emitters may be positioned such that, when viewed in plan view, none of the positions of any of the emitters overlap with each other. The emitters may be positioned such that, when viewed in plan view, positions of at least two of the emitters overlap with each other. Two or more, or even each, of the emitters may be disposed at a different vertical position. The apparatus may include an additional emitter positioned to emit a beam through the central axis directly to the shared exit point without being received by an interleaving mirror. The beam stack may include the beam of the additional emitter. The additional emitter may be disposed at a vertical height different from (e.g., higher than or lower than) vertical heights of all of the emitters.

The apparatus may include a base mount defining a plurality of flat platforms. Two or more, or even each, of the emitters may be disposed on or over a different platform. The base mount may define therein a plurality of cooling channels configured to accommodate cooling fluid for cooling of the emitters. Two or more, or even each, of the flat platforms may be disposed at a different vertical height. The base mount may define an opening configured to accommodate, and transmit therethrough, the beam stack at the shared exit point. Two or more, or even each, of the interleaving mirrors may have different widths. The widths of all of the interleaving mirrors may be equal to each other.

In another aspect, embodiments of the invention feature a method of beam stacking. A plurality of beam emitters is disposed around a central axis. Each beam emitter is caused to emit a beam toward the central axis. The beams are received at the central axis and directed to a shared exit point, the beams overlapping in at least one dimension at the shared exit point, to thereby form a beam stack.

Embodiments of the invention may include one or more of the following in any of a variety of combinations. The optical path lengths of the beams, each extending from one of the beam emitters to the shared exit point, may be equal to each other. Each beam emitter may be configured to emit only a single beam. The beams may be received at the central axis, and redirected, by one or more mirrors. The beams may be received at the central axis by a plurality of interleaving mirrors. Each interleaving mirror may receive one or more of the beams. An additional beam may be emitted through the central axis, without redirection of the additional beam, directly to the shared exit point. The beam stack may include the additional beam. Two or more, or even each, of the beam emitters may be disposed at a different vertical position. Two or more, or even each, of the beam emitters may include, consist essentially of, or consist of a diode emitter. Two or more, or even each, of the beams may be collimated in the fast axis between its beam emitter and the central axis. The beam stack may be collimated in the slow axis. The beam stack may be collimated at the shared exit point.

One or more, or even each, of the beam emitters may be cooled. The beam stack may be coupled into an optical fiber. The workpiece may be processed with the beam stack. Processing the workpiece may include, consist essentially of, or consist of cutting, welding, etching, annealing, drilling, soldering, and/or brazing. Processing the workpiece may include, consist essentially of, or consist of physically altering at least a portion of a surface of the workpiece.

The beam stack may be wavelength-beam combined with one or more additional beam stacks to thereby form a wavelength-beam-combining (WBC) output beam. The beam stack and the one or more additional beam stacks may each include, consist essentially of, or consist of the same number of stacked beams. The workpiece may be processed with the WBC output beam. Processing the workpiece may include, consist essentially of, or consist of cutting, welding, etching, annealing, drilling, soldering, and/or brazing. Processing the workpiece may include, consist essentially of, or consist of physically altering at least a portion of a surface of the workpiece.

In yet another aspect, embodiments of the invention feature a wavelength-beam-combining (WBC) laser system that includes, consists essentially of, or consists of a plurality of beam-stacking modules, a dispersive element, and a partially reflective output coupler. Each beam-stacking module is configured to stack a plurality of emitted beams in at least one dimension and output a beam stack that includes, consists essentially of, or consists of the beams. The dispersive element is positioned to receive the plurality of beam stacks and combine the beam stacks into a combined beam. The output coupler is positioned to receive the combined beam, transmit a first portion of the combined beam as a WBC output beam, and reflect a second portion of the combined beam back toward the dispersive element and thence to beam emitters of the modules to stabilize emission wavelengths thereof.

Embodiments of the invention may include one or more of the following in any of a variety of combinations. For two or more of the beam-stacking modules, or even each beam-stacking module, (i) the beam-stacking module may include, consist essentially of, or consist of a plurality of beam emitters each configured to emit one of the beams, and (ii) optical paths of each of the beams, from its beam emitter to a shared exit point of the beam stack from the beam-stacking module, may be equal to each other. Two or more, or even each, beam-stacking module may include, consist essentially of, or consist of a plurality of beam emitters each configured to emit one of the beams toward a central axis, and a plurality of interleaving mirrors disposed at the central axis, each interleaving mirror receiving one of the beams and redirecting it to a shared exit point. The laser system may include a plurality of first lenses disposed optically upstream of the dispersive element. Each first lens may be configured to receive a beam stack from one of the beam-stacking modules and converge chief rays of the beam stack toward the dispersive element. The laser system may include, disposed optically upstream of the dispersive element, a second lens configured to receive all of the beam stacks and collimate rays thereof. The laser system may include an optical telescope disposed optically downstream of the dispersive element and optically upstream of the output coupler. The dispersive element may include, consist essentially of, or consist of a reflective diffraction grating or a transmissive diffraction grating. The dispersive element may include, consist essentially of, or consist of a diffraction grating and one or more prisms. The beam-stacking modules may be mechanically positioned to converge the beam stacks toward the dispersive element. Two or more, or even each, of the beam stacks may be stacked along a fast axis of the beams thereof.

In another aspect, embodiments of the invention feature a base mount for a beam-stacking module. The base mount includes, consists essentially of, or consists of a base plate and an annular platform disposed over the base plate. The annular platform has a top surface and a curved outer surface. The top surface defines a plurality of flat steps each having a different vertical height above the base plate and each configured to accommodate a beam emitter thereon. The outer surface defines an opening, extending through a thickness of the annular platform, having a height extending at least from a vertical height of a lowest one of the flat steps to a vertical height of a highest one of the flat steps.

Embodiments of the invention may include one or more of the following in any of a variety of combinations. The base plate and/or the annular platform may define a series of hollow cooling channels therethrough. The opening may be disposed directly across from the highest one of the flat steps or directly across from the lowest one of the flat steps. The base mount may include a plurality of interleaving mirrors disposed within the annular platform and surrounded by the plurality of flat steps. The number of the interleaving mirrors may be no greater than a number of the flat steps. The number of interleaving mirrors may be equal to the number of flat steps, or may be one less than the number of flat steps.

These and other objects, along with advantages and features of the present invention herein disclosed, will become more apparent through reference to the following description, the accompanying drawings, and the claims. Furthermore, it is to be understood that the features of the various embodiments described herein are not mutually exclusive and may exist in various combinations and permutations. As used herein, the term “substantially” means ±10%, and in some embodiments, ±5%. The term “consists essentially of” means excluding other materials that contribute to function, unless otherwise defined herein. Nonetheless, such other materials may be present, collectively or individually, in trace amounts. Herein, the terms “radiation” and “light” are utilized interchangeably unless otherwise indicated. Herein, “downstream” or “optically downstream,” is utilized to indicate the relative placement of a second element that a light beam strikes after encountering a first element, the first element being “upstream,” or “optically upstream” of the second element. Herein, “optical distance” between two components is the distance between two components that is actually traveled by light beams; the optical distance may be, but is not necessarily, equal to the physical distance between two components due to, e.g., reflections from mirrors or other changes in propagation direction experienced by the light traveling from one of the components to the other. Distances utilized herein may be considered to be “optical distances” unless otherwise specified.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawings, in which:

FIGS. 1A and 1B are, respectively, a three-dimensional model and a schematic top view of a conventional arrangement of laser emitters for beam stacking;

FIGS. 2A and 2B are, respectively, a three-dimensional model and a schematic top view of a helical arrangement of laser emitters for beam stacking in accordance with various embodiments of the present invention;

FIG. 2C is a schematic of the beam path from one of the emitters in the helical arrangement of FIGS. 2A and 2B to an interleaving mirror and thence to a shared exit point;

FIG. 2D depicts an arrangement of interleaving mirrors utilized in the helical arrangement of FIGS. 2A and 2B in accordance with various embodiments of the present invention;

FIGS. 3A and 3B are, respectively, a three-dimensional model and a schematic top view of a helical arrangement of laser emitters for beam stacking in accordance with various embodiments of the present invention;

FIG. 3C depicts an arrangement of interleaving mirrors utilized in the helical arrangement of FIGS. 3A and 3B in accordance with various embodiments of the present invention;

FIGS. 4A and 4B are, respectively, a three-dimensional model and a schematic top view of a helical arrangement of laser emitters for beam stacking in accordance with various embodiments of the present invention;

FIGS. 5A, 5B, and 5C are, respectively, a three-dimensional model, a schematic side view, and a schematic top view of a helical arrangement of laser emitters for beam stacking in accordance with various embodiments of the present invention;

FIG. 6 depicts an exemplary base mount, or heat sink, for a helical arrangement of emitters in accordance with various embodiments of the present invention; and

FIG. 7 is a schematic diagram of a laser system that combines sets of stacked beams from multiple input helical arrangements of laser emitters in accordance with various embodiments of the invention.

### DETAILED DESCRIPTION

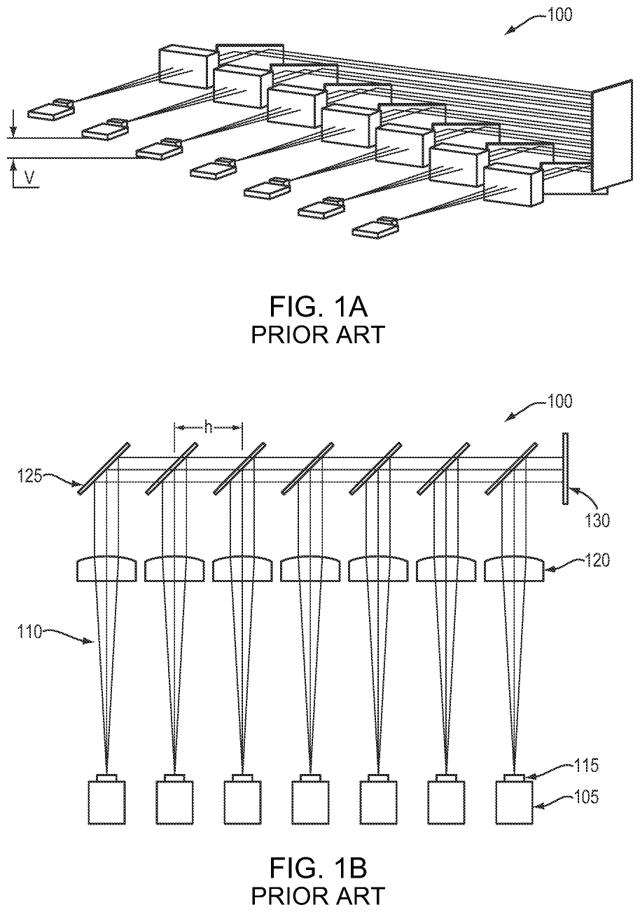

FIGS. 1A and 1B depict, as a three-dimensional model (FIG. 1A) and a schematic top view (FIG. 1B), a conventional arrangement 100 of seven single emitters 105 for linear vertical stacking along the fast axis of the emitted beams 110. FIGS. 1A and 1B show three “rays” being emitted from each of the emitters 105; however, these rays constitute a single beam from the single emitter, where the center ray represents the chief ray of the beam while the peripheral rays represent the approximate geometric spread of the beam. As shown, the individual beams 110 are first collimated, in the fast axis, by FAC lenses 115 that are each associated with one of the emitters. Each of the beams is then collimated, in the slow axis, by SAC lenses 120 that are each associated with one of the emitters. The collimated beams are then reflected by a set of interleaving mirrors 125 to a virtual common surface 130, thereby forming the vertical stack of beams. As may be observed in the figures, the stacked beams appear to fully overlap in the top view of FIG. 1B (i.e., in the slow axis), and FIG. 1A shows the spatial separation of the stacked beams in the vertical dimension (i.e., in the fast axis).

As is evident in FIGS. 1A and 1B, the conventional linear stacking arrangement 100 is relatively bulky. In order to stack the beams without obstruction, the arrangement 100 of FIGS. 1A and 1B requires not only a vertical offset v between the emitters 105, but also a horizontal offset h. In this case, the minimum horizontal offset h between two adjacent emitters 105 is the width of an individual SAC lens 120. As also shown, the horizontal offsets h result in different optical paths traversed by each of the beams 110 between their emitter 105 and the virtual surface 130. This optical path difference will degrade the overall beam quality measured at or optically downstream of the surface 130, reduce fiber-coupling efficiency of the stacked beams, and increase the fiber-coupling numerical aperture (NA) of the stacked beams. The optical path difference also renders the stacking arrangement 100 of FIGS. 1A and 1B unsuitable for various applications and systems, including WBC techniques and systems, which require substantially equal optical paths for individual emitters in order to assure stable and efficient WBC and to produce the highest beam quality of the combined beams. In addition, the conventional arrangement 100 of FIGS. 1A and 1B requires separate SAC lenses 120 for each individual emitter 105, which complicates the arrangement and packaging thereof, and which also increases the total system cost.

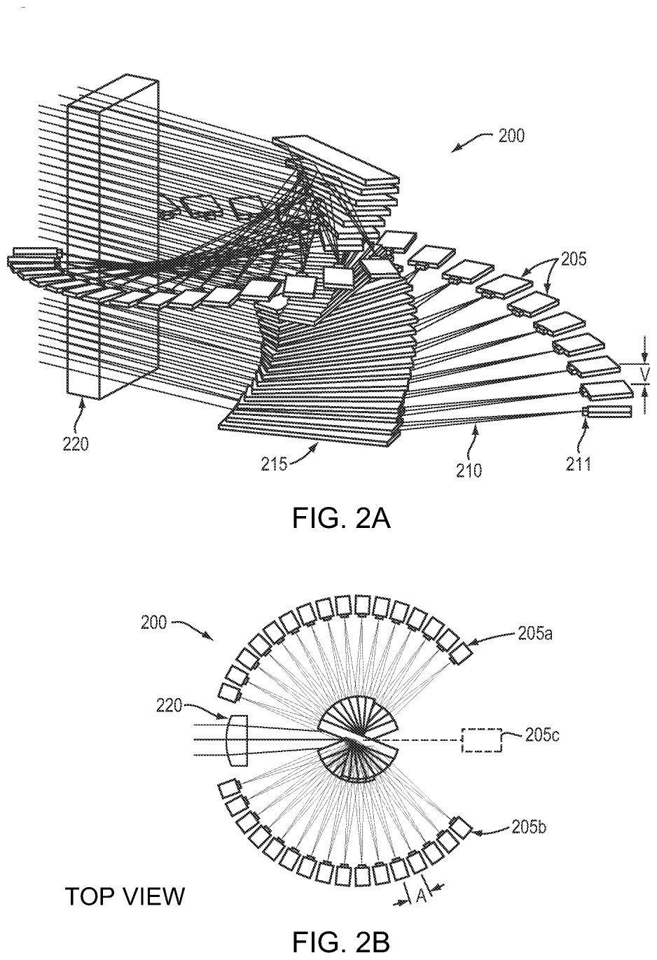

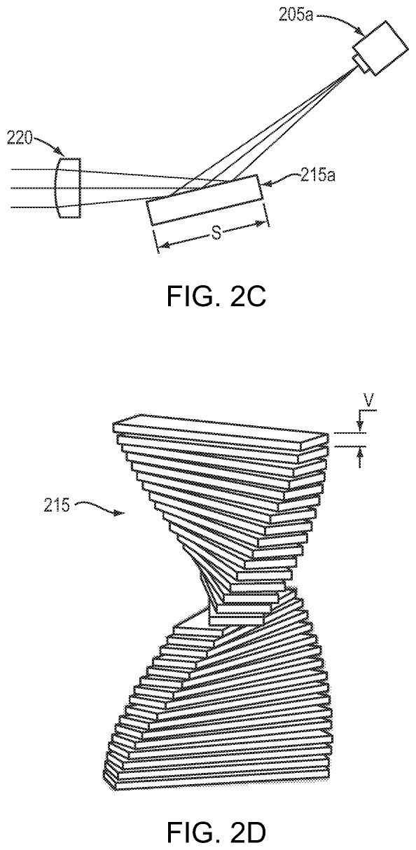

FIGS. 2A and 2B depict, as a three-dimensional model (FIG. 2A) and a schematic top view (FIG. 2B), a helical arrangement 200 of 32 single emitters 205 for beam stacking along the fast axis in accordance with embodiments of the present invention. As shown, the emitters 205 are offset from each other vertically (v) and laterally (A), and the emitters 205 are arranged such that, when viewed from the top (FIG. 2B), they form two arcs of a circle and emit their beams 210 to the central axis of the circle. While the circular arcs formed by the emitters 205 are equal in size and symmetric about a diameter of the circle, in various embodiments these need not be the case. While FIGS. 2A and 2B depict the stacking of beams from 32 emitters 205, various embodiments of the invention may include more or fewer than 32 emitters. In general, in embodiments featuring fewer than 32 emitters, the emitters may be located closer to the central axis of the circle, while in embodiments featuring more than 32 emitters, this distance may be increased to accommodate the larger number of emitters.

As shown in FIG. 2A, at the center of the helical arrangement of emitters 205 is disposed a stack of 32 interleaving mirrors 215 (also shown in FIG. 2D), with one mirror 215 being vertically disposed at the same height as one of the emitters 205 and angled to receive the beam 210 from that emitter 205 and reflect it to a common exit point from the helical arrangement. That is, the interleaving mirrors 215 may be stacked having a vertical spacing of v equal to that of the vertical spacing between emitters. In various embodiments, this spacing v is kept as small as possible, as the vertical size of the final output beam stack is dictated, at least in part, by the spacing v. For example, the vertical size of the output beam stack may be approximately equal to (N−1)×v, where N is the total number of emitters 205.

As shown, in various embodiments, a single SAC lens 220 may be disposed at the common exit point and may therefore collimate all of the 32 stacked beams in the slow axis. The helical arrangement 200 of FIGS. 2A and 2D has the advantage of being very compact. In addition, helical arrangements in accordance with various embodiments of the invention provide beam path lengths, for each of the beams 210 between its emitter 205 and the common exit point (and/or SAC lens 220) that are equal to each other. Moreover, the arrangement 200 utilizes a single SAC lens 220, reducing costs and complexity when compared to conventional emitter arrangements.

As shown in FIGS. 2B and 2C, the emitters 205 are arranged in two symmetric arcs, or “staircases,” and in each of which are spaced apart vertically and horizontally by consistent offsets. In the particular exemplary arrangement shown in FIGS. 2A and 2B, all of the emitters of one staircase are disposed vertically above all of the emitters of the other staircase, although that need not be the case, as will be detailed further below. In addition, the two staircases are depicted as being symmetric about a diameter of the resulting circle (as viewed from above) and each containing the same number of emitters; this is not necessarily the case in accordance with other embodiments of the invention.

The emitters labeled 205a and 205b in FIG. 2B are the two emitters at the ends of their respective circular (when viewed from above) arcs farthest away from the common beam exit point (and thus SAC lens 220). These emitters 205a, 205b are the two emitters emitting beams 210 having the smallest grazing angles with their respective interleaving mirrors 215. In the modelled arrangement of FIGS. 2A-2D, this smallest grazing angle is 20°, but embodiments of the invention may feature smallest grazing angles that are smaller or larger than 20°. In fact, this smallest grazing angle may be reduced in order to accommodate a larger number of emitters in the arrangement or to reduce the overall dimensions of the arrangement itself. As shown in FIG. 2C, the emitter 205a (or 205b) having the smallest grazing angle requires the largest interleaving mirror 215a to accommodate the geometric extent of the grazing beam. Thus, in various embodiments, the interleaving mirrors associated with the emitter(s) having the smallest grazing angles will have the largest size s (e.g., width), and the size of the remaining interleaving mirrors 215 may be decreased for the remaining emitters, which have larger grazing angles thereto. The interleaving mirrors 215 may therefore have a variety of sizes, depending upon the grazing angles. For example, each of the symmetric circular arcs (as viewed from above) of the emitters in the arrangement of FIG. 2B contains 16 emitters, and thus the interleaving mirrors 215 may have 16 different sizes, two of each size. In various embodiments, all of the interleaving mirrors 215 have the same size s for simplicity, and that minimum size s is dictated by the smallest grazing angle.

In various embodiments, the minimum size s may be defined by s=b+c, where b is the beam size on the interleaving mirror, and c is an optional additional clearance, e.g., approximately 5% to approximately 10% of the beam size, approximately 1 mm to approximately 6 mm, or approximately 1 mm to approximately 10 mm. The beam size may be estimated by b≈d×tan(θ)/sin(α), where d is the distance from the emitter to the interleaving mirror, θ is the emitter slow-axis full-power (e.g., approximately 99% power content) full divergence angle, and α is the smallest grazing angle. For example, if d=60 mm, θ=12, α=20°, and c=10%×b, then s≈40 mm.

As shown in FIG. 2B, when viewed from above, there is a gap (i.e., a space larger than the spacing A utilized between pairs of adjacent emitters) between emitter 205a and emitter 205b due to the grazing angles of the beams emitted by these emitters. That is, the size s of the interleaving mirrors 215, at least for these emitters, is selected such that a smaller grazing angle may not be accommodated. Thus, the size of this gap may be decreased by increasing the size of the interleaving mirrors 215 (at least those associated with emitters 205a, 205b) and thus decreasing the smallest grazing angle that may be accommodated by the arrangement.

As also shown in FIG. 2B, this gap between emitters 205a, 205b may be utilized to accommodate the beam from an additional emitter 205c. As shown, in various embodiments, emitter 205c is located directly across from the central axis of the arrangement from the common beam exit point (and therefore SAC lens 220). That is, in various embodiments, emitter 205c, the central axis of the helical arrangement, and the common exit point (e.g., SAC lens 220) are collinear when viewed from above. Thus, in various embodiments, the beam emitted by emitter 205c does not require redirection by an interleaving mirror 215, and no interleaving mirror 215 is associated with emitter 205c. Therefore, in various embodiments of the invention, the number of interleaving mirrors 215 in the helical arrangement may be less (e.g., by one) than the number of emitters 205 in the arrangement. In various embodiments, the emitter 205c may be vertically disposed at the top of the arrangement, i.e., at a vertical height higher than that of any of the other emitters 205. In various embodiments, the beam emitted by emitter 205c may be utilized as a reference for alignment of the other beams in the arrangement.

As shown, all of the emitters 205 in the helical arrangement (except for emitter 205c, if present) each utilize a corresponding interleaving mirror 215 angled at the proper angle to redirect the beam 210 from the emitter 205 to the common exit point. Thus, in various embodiments of the invention, the chief rays (i.e., the center lines of the beams in their propagation direction) of the beams 210 are substantially parallel to each other after being reflected by the interleaving mirrors 215 and at the common exit point (e.g., at SAC lens 220).

In the helical arrangement 200 depicted in FIGS. 2A and 2B, the emitters 205 in each of the two arcs (or “staircases”) are evenly spaced apart with a vertical offset v and a radial offset angle A between adjacent emitters. The interleaving mirrors 215 are accordingly stacked, as shown in FIG. 2D, with a vertical offset v between adjacent mirrors and with a rotation angle that varies with at an interval of A/2 between adjacent mirrors. In various embodiments, the interleaving mirrors 215 may be individually aligned at the proper heights and rotation angles and then fastened together (e.g., via an adhesive), or they may be assembled into a unitary mirror arrangement before being introduced into the helical arrangement of emitters. Thus, while the arrangement of interleaving mirrors may include, consist essentially of, consist of, or be fabricated from multiple interleaving mirrors each associated with one of the emitters, embodiments of the invention include central unitary (e.g., multi-faceted) mirrors or reflectors configured to receive each of the beams and reflect it at the proper angle to the shared exit point. Such mirrors may be more complex but may be designed via optical modeling and fabricated from one or more reflective materials (e.g., metals) via techniques such as three-dimensional printing.

The helical arrangement 200 of FIGS. 2A and 2B forms a single spiral arrangement in which the heights of the emitters 205 increase around the entire perimeter of the arrangement, and emitter 205a is at the bottom while emitter 205b is located at the top of the arrangement. In principle, this needs not be the case, and any of the emitters may be located at the top or bottom of the arrangement.

In the exemplary arrangement 200 of FIGS. 2A and 2B, each emitter 205 is a single emitter (e.g., a diode emitter), and thus stacking of the beams 210 in the vertical axis (i.e., the fast axis) enables the use of a single shared SAC lens 220, greatly simplifying the assembly and reducing system costs. In principal, embodiments of the invention may stack beams from multi-beam emitters (e.g., diode bars, etc.) that emit more than one beam each along the slow axis. In such embodiments, more complicated optics, such as imaging and/or telescopic optics, may be utilized to account for the multiple beams along the slow axis. Thus, while embodiments of the invention provide many advantages and enable the use of single emitters, as detailed herein, other embodiments of the invention may feature arrangements of multi-beam emitters and stacking of the beams emitted thereby.

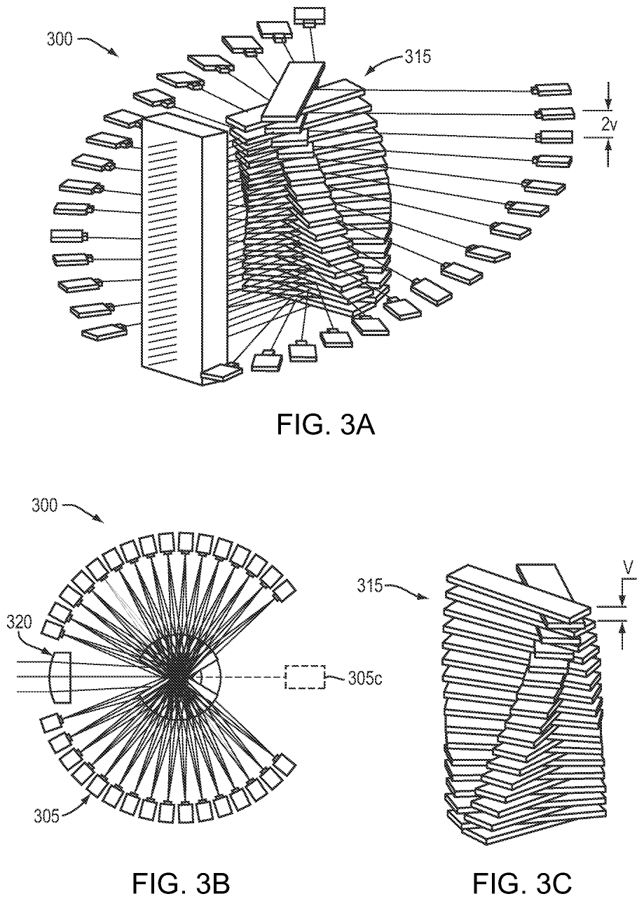

While the helical arrangement 200 of FIGS. 2A and 2B effectively formed a single staircase of ascending emitters as the perimeter of the arrangement is traversed, embodiments of the present invention encompass other helical arrangements. For example, FIGS. 3A and 3B depict another helical arrangement 300 in which the two staircases of emitters are vertically interleaved with each other. As in the helical arrangement 200 of FIGS. 2A and 2B, in this helical arrangement multiple single emitters 305 form two staircases and emit beams each having the same optical path length between their emitter 305 and a common shared exit point. As shown, the beams are reflected by interleaving mirrors 315 to the shared exit point, where a SAC lens 320 is disposed in the illustrated embodiment.

The top view of FIG. 3B is virtually the same as that shown in FIG. 2B. As also shown, an additional emitter 305c lacking a corresponding interleaving mirror 315 may be provided directly across from the shared exit point. In various embodiments, as described above for emitter 205c, emitter 305c may be vertically located at the top of the arrangement (i.e., located at a vertical height higher than that of any other emitter), and the beam from emitter 305c may be utilized for, e.g., alignment of the remaining beams (e.g., via rotation of the various interleaving mirrors 315).

While the interleaving mirrors 215 formed a single rotational spiral, as shown in FIG. 3C the interleaving mirrors 315 are mutually cross-stacked and form two interleaved spirals. As shown, although the vertical spacing v between two adjacent mirrors 315 remains the same as in FIG. 2D, the vertical spacing between two adjacent emitters 305 is now 2v since the two staircases of emitters are interleaved with each other.

The helical arrangement 300 of FIGS. 3A-3C, featuring two interleaved staircases of emitters, may provide various advantages over the single-spiral arrangement 200 of FIGS. 2A and 2B. For example, the arrangement 300 of FIGS. 3A and 3B is more structurally symmetric, which may simplify the design of the base on which the emitters 305 are disposed (not shown). In addition, the assembly of interleaving mirrors 315 may be more structurally stable.

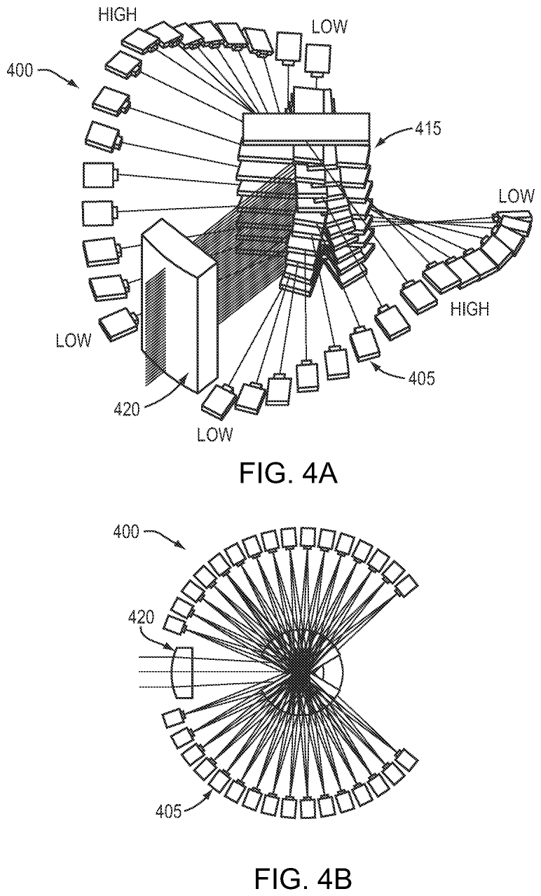

Embodiments of the present invention include helical emitter arrangements that are more complex than those shown in FIGS. 2A and 3A, in which the emitters, respectively, are arranged in a single ascending spiral staircase and two interleaved staircases. For example, FIGS. 4A and 4B depict one such helical arrangement 400, in which emitters 405 form four staircases of emitters yet still emit beams all having equal optical path lengths between their emitter and the common exit point of the helical arrangement. As shown, the beams are reflected by interleaving mirrors 415 to the shared exit point, where a shared SAC lens 420 is disposed in the illustrated embodiment. The labels “High” and “Low” on FIG. 4A represent the top and bottom points of the staircases formed by the emitter arrangement 400. As also shown, when viewed from above, i.e., in the top view of FIG. 4B, the helical arrangement 400 of FIG. 4A is virtually identical to those shown in FIGS. 2B and 3B.

As in the example helical arrangements 200, 300 of FIGS. 2A and 3A, the interleaving mirrors 415 in the helical arrangement of FIG. 4A are stacked with the same minimum vertical spacing v. However, in this embodiment, the vertical spacing between two adjacent emitters 405 on the same ascending or descending staircase is equal to 4v.

While the helical arrangements of FIGS. 2A, 3A, and 4A include fairly consistent and regular positioning of vertically adjacent emitters, in principle, emitters may be arranged in any random staircase, i.e., a staircase which may proceed up or down with a discrete vertical spacing between adjacent emitters ranging from a minimum of v to a maximum of (N−1)×v, where N is the total number of emitters, as long as no two emitters are positioned at the same vertical level and do not overlap with each other when viewed from above. Still, in any such embodiments, the interleaving mirrors utilized to redirect the beams may be stacked with a vertical spacing of v; this minimum spacing is advantageous for reducing the overall beam stack size in the stacking direction.

As mentioned above, in the arrangements of FIGS. 2A, 3A, and 4A, none of the emitters overlap with each other when viewed from above (see FIGS. 2B, 3B, and 4B); that is, no two of the emitters occupy the same angular position of the circular helix. However, this need not be the case, and various embodiments of the invention feature multi-helix arrangements effectively formed of vertical stacks of multiple ones of the helical arrangements described above. While such multi-helix arrangements may be, for a given number of emitters, larger in size vertically, they may also enable a more compact horizontal structure in which the distance from each emitter to the central axis of the arrangement is decreased.

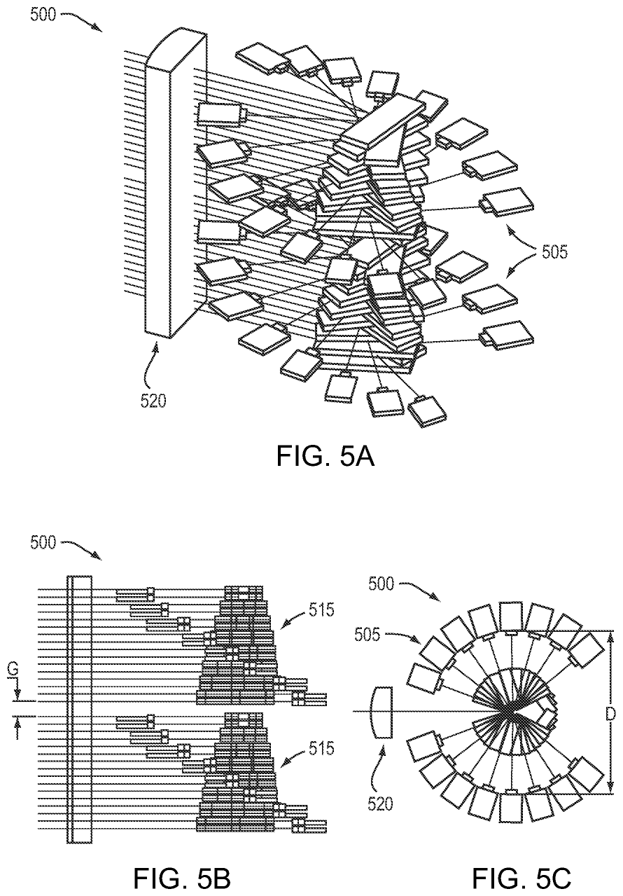

FIGS. 5A-5C depict one such example multi-helix emitter arrangement 500 in which emitters are arranged in two vertically stacked helixes. As in the arrangements of FIGS. 2A, 3A, and 4A, the depicted arrangement 500 features 32 single emitters 505 emitting beams, reflected by interleaving mirrors 515, having equal optical path lengths to a common exit point, at which is disposed a single shared SAC lens 520. In the depicted example, the emitters 505 are arranged in two parallel helixes, such that, when viewed from above (see FIG. 5C), two emitters 505 overlap at each angular position within the circular arrangement. Each of the helical arrangements of FIG. 5A is equivalent to the dual staircase arrangement of FIG. 3A, but in other embodiments each helix may be arranged differently (e.g., with a different number of staircases of emitters), and/or each helix may have an arrangement different from the other. As shown in FIG. 5B, in various embodiments a multi-helix arrangement may include a vertical gap G between helixes, where G is greater than the vertical spacing between adjacent emitters in each helix, due to, for example, structural limitations for support of the emitter helixes. Such a gap may slightly increase the vertical size of the stacked beams at the output.

As mentioned above, one advantage of the multi-helix arrangement of FIG. 5A is a dramatic reduction in the spiral diameter D of the arrangement (see FIG. 5C) compared to the single-helix arrangements of FIGS. 2A, 3A, and 4A. However, the arrangement of FIG. 5A may require a more complex base mount (not shown) on which the emitters are positioned. As will be shown later, the base mount for the emitters in various embodiments of the invention may include, consist essentially of, or consist of a stepped platform, and/or heat sink, having flat steps to support the individual emitters. In various embodiments, the base mount may incorporate internal cooling channels to accommodate a flowing cooling fluid to thereby cool the emitters during operation.

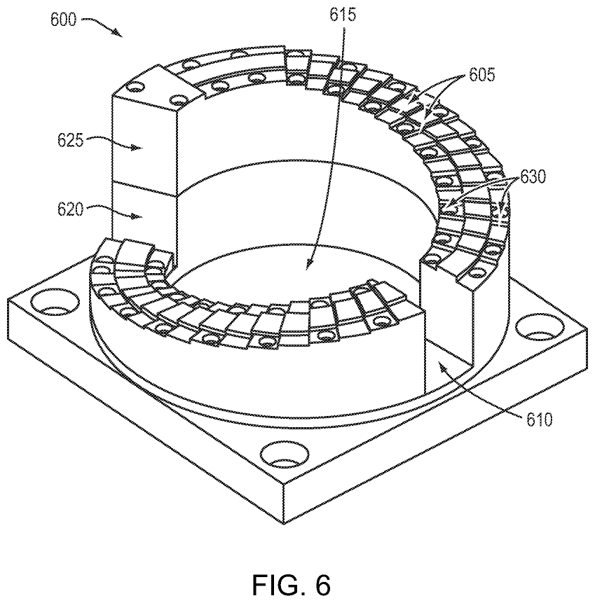

FIG. 6 depicts a base mount 600, or heat sink, for a helical arrangement of emitters in accordance with embodiments of the present invention. In the depicted example, the base mount 600 is designed to support the emitters arranged in the helical arrangement 200 of FIG. 2A. As shown, the base mount 600 includes a spiral staircase of flat steps 605 each configured to support one of the emitters at the proper vertical position in the arrangement. The base mount 600 also features a cut-out 610 at the shared exit point for the beams, at or on which may be mounted shared optics such as a SAC lens, a waveplate, a window, etc. The base mount 600 also features a base plate 615 having a flat central area configured to support the stack of interleaving mirrors utilized to redirect the beams to the shared exit point.

In the example embodiment depicted in FIG. 6, the base mount 600 includes a base portion 620 that directly supports one of the staircases of emitters and forms a base for a staircase portion 625 that defines the steps for the other staircase of emitters. The base mount 600 also includes various mounting holes 630 that may accommodate mounting hardware (e.g., screws or other fasteners) to attach staircase portion 625 to base portion 620 and seal any cooling channels (not shown) inside the staircase portion 625 and base portion 620. Since in embodiments of the present invention, the emitters are single emitters and are spaced apart from each other (e.g., vertically and angularly/horizontally), the base plate need not include internal cooling channels, particularly if the emitters emit power at fairly low levels (e.g., below 2 Watts of power each). In such embodiments, the base mount may be a single unitary part and the mounting holes 630 may be omitted. While the base mount 60 of FIG. 6 is configured to accommodate the helical arrangement 200 of FIG. 2A, other base mounts may be provided to accommodate the other emitter arrangements detailed herein in accordance with embodiments of the present invention.

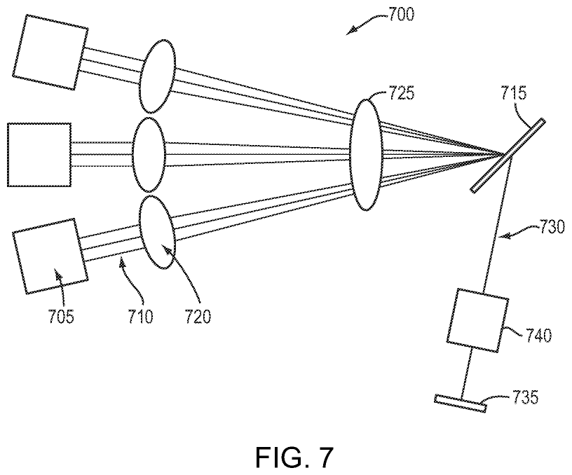

Once the helical emitter arrangements in accordance with embodiments of the invention are utilized to stack beams in one dimension, the stacked beams may be utilized as an input for a more complex laser system such as a WBC laser system. FIG. 7 schematically depicts one such WBC system 700 that combines sets of stacked beams from three different input helical arrangements, or “modules,” in accordance with embodiments of the invention. FIG. 7 depicts the WBC system 700 in the WBC, or beam-combining, dimension. Each of the helix modules 705 in the system of FIG. 7 may include any of the helical emitter arrangements detailed above. The lines 710 represent the chief rays of the beams from the individual beam stacks emitted by each module 705. While only three lines 710 are shown for each helix module 705 for clarity, each helix module 705 may form beam stacks utilizing more than three individual emitters, in various embodiments of the invention.

As shown in FIG. 7, the helix modules 705 are individually angled such that the beam stacks emitted thereby (and therefore their exit points and SAC lenses, if present) converge toward a dispersive element 715 (which may include, consist essentially of, or consist of, e.g., a diffraction grating). As also shown, a lens 720 may be associated with each module 705 to converge the chief rays emitted thereby to the dispersive element 715. In addition, a shared lens 725 may collimate the beam stacks from all of the modules before the beam stacks are incident on the dispersive element 715. Note that, in typical embodiments, the convergence (and/or overlap) of the chief rays at the dispersive element 715 is primarily due to the geometric arrangement/angling of the helix modules 705, rather than the focusing power of the lens 725.

At the dispersive element 715, the beams from the modules 705 are combined into a single beam 730, which propagates to a partially reflective output coupler 735. The beam 730 may be a multi-wavelength beam since, in various embodiments, the wavelengths of some, if not all, of the emitters in the helix modules 705 are different. At the coupler 735, a first portion of the beam 730 is output from the system as the WBC output beam, while a reflected second portion of the beam 730 propagates back to the individual emitters in the modules 705 for feedback and wavelength locking (i.e., to stabilize the emission wavelengths of the emitters). One or more optional optical systems 740 may be disposed optically downstream of the dispersive element 715 and optically upstream of the output coupler 735, for one or more purposes such as beam shaping, imaging, beam redirection or repositioning, and/or cross-coupling mitigation. For example, optical system 740 may include, consist essentially of, or consist of an optical telescope for mitigation of optical cross-talk, as disclosed in U.S. Pat. No. 9,256,073, filed on Mar. 15, 2013, and U.S. Pat. No. 9,268,142, filed on Jun. 23, 2015, the entire disclosures of which are hereby incorporated by reference herein.

In the WBC laser system 700 of FIG. 7, each helix module 705 may be considered to be conceptually similar to a diode bar utilized in conventional WBC systems. However, the WBC system 700 of FIG. 7 utilizes optically stacked single emitters rather than packaged multiple-emitters such as diode bars. This provides several advantages. For example, since the beams are stacked in the fast axis direction, there is no need for the use of optical rotators or twisters, simplifying the system and preventing complications such as clipping loss and optical aberration. In addition, in the helix modules 705 there is no emitter smile, which can substantially reduce WBC beam quality and impact wavelength locking. In addition, the system 700 of FIG. 7 may be operated at significantly lower operating currents, because the single emitters of the modules 705 may be easily electrically connected in series. In addition, since the single emitters are spaced apart from each other, there is less or no thermal crosstalk between individual emitters, and therefore cooling systems (e.g., which may utilize flowing coolant fluid) utilized for the system 700 of FIG. 7 may be much less complex or omitted entirely.

In various embodiments of the present invention, the output beams of laser systems including one or more helical emitter arrangements (e.g., laser system 700) may be propagated, e.g., via a fiber optic module, to a delivery optical fiber (which may be coupled to a laser delivery head) and/or utilized to process a workpiece. For example, the output beam from laser system depicted in FIG. 7 may be coupled into a delivery fiber, or the output beam may be combined with the output beams of one or more other laser systems (via, e.g., polarization beam combining, spatial beam combining, etc.), and the combined beam may be coupled into a delivery fiber for processing of a workpiece.

In various embodiments, a laser head contains one or more optical elements utilized to focus the output beam onto a workpiece for processing thereof. For example, laser heads in accordance with embodiments of the invention may include one or more collimators (i.e., collimating lenses) and/or focusing optics (e.g., one or more focusing lenses). A laser head may not include a collimator if the beam(s) entering the laser head are already collimated. Laser heads in accordance with various embodiments may also include one or more protective window, a focus-adjustment mechanism (manual or automatic, e.g., one or more dials and/or switches and/or selection buttons). Laser heads may also include one or more monitoring systems for, e.g., laser power, target material temperature and/or reflectivity, plasma spectrum, etc. A laser head may also include optical elements for beam shaping and/or adjustment of beam quality (e.g., variable BPP) and may also include control systems for polarization of the beam and/or the trajectory of the focusing spot. In various embodiments, the laser head may include one or more optical elements (e.g., lenses) and a lens manipulation system for selection and/or positioning thereof for, e.g., alteration of beam shape and/or BPP of the output beam, as detailed in U.S. patent application Ser. No. 15/188,076, filed on Jun. 21, 2016, the entire disclosure of which is incorporated by reference herein. Exemplary processes include cutting, piercing, welding, brazing, annealing, etc. The output beam may be translated relative to the workpiece (e.g., via translation of the beam and/or the workpiece) to traverse a processing path on or across at least a portion of the workpiece.

In embodiments utilizing an optical delivery fiber, the optical fiber may have many different internal configurations and geometries. For example, the optical fiber may include, consist essentially of, or consist of a central core region and an annular core region separated by an inner cladding layer. One or more outer cladding layers may be disposed around the annular core region. Embodiments of the invention may incorporate optical fibers having configurations described in U.S. patent application Ser. No. 15/479,745, filed on Apr. 5, 2017, U.S. patent application Ser. No. 15/879,500, filed on Jan. 25, 2018, and U.S. patent application Ser. No. 16/675,655, filed on Nov. 6, 2019, the entire disclosure of each of which is incorporated by reference herein.

In various embodiments, a controller may control the motion of the laser head or output beam relative to the workpiece via control of, e.g., one or more actuators. The controller may be present in laser systems featuring helical emitter arrangements as disclosed herein. The controller may also operate a conventional positioning system configured to cause relative movement between the output laser beam and the workpiece being processed. For example, the positioning system may be any controllable optical, mechanical or opto-mechanical system for directing the beam through a processing path along a two- or three-dimensional workpiece. During processing, the controller may operate the positioning system and the laser system so that the laser beam traverses a processing path along the workpiece. The processing path may be provided by a user and stored in an onboard or remote memory, which may also store parameters relating to the type of processing (cutting, welding, etc.) and the beam parameters necessary to carry out that processing. The stored values may include, for example, beam wavelengths, beam shapes, beam polarizations, etc., suitable for various processes of the material (e.g., piercing, cutting, welding, etc.), the type of processing, and/or the geometry of the processing path.

As is well understood in the plotting and scanning art, the requisite relative motion between the output beam and the workpiece may be produced by optical deflection of the beam using a movable mirror, physical movement of the laser using a gantry, lead-screw or other arrangement, and/or a mechanical arrangement for moving the workpiece rather than (or in addition to) the beam. The controller may, in some embodiments, receive feedback regarding the position and/or processing efficacy of the beam relative to the workpiece from a feedback unit, which will be connected to suitable monitoring sensors.

The controller may be provided as either software, hardware, or some combination thereof. For example, the system may be implemented on one or more conventional server-class computers, such as a PC having a CPU board containing one or more processors such as the Pentium or Celeron family of processors manufactured by Intel Corporation of Santa Clara, Calif., the 680x0 and POWER PC family of processors manufactured by Motorola Corporation of Schaumburg, Ill., and/or the ATHLON line of processors manufactured by Advanced Micro Devices, Inc., of Sunnyvale, Calif. The processor may also include a main memory unit for storing programs and/or data relating to the methods described herein. The memory may include random access memory (RAM), read only memory (ROM), and/or FLASH memory residing on commonly available hardware such as one or more application specific integrated circuits (ASIC), field programmable gate arrays (FPGA), electrically erasable programmable read-only memories (EEPROM), programmable read-only memories (PROM), programmable logic devices (PLD), or read-only memory devices (ROM). In some embodiments, the programs may be provided using external RAM and/or ROM such as optical disks, magnetic disks, as well as other commonly used storage devices. For embodiments in which the functions are provided as one or more software programs, the programs may be written in any of a number of high level languages such as FORTRAN, PASCAL, JAVA, C, C++, C#, BASIC, various scripting languages, and/or HTML. Additionally, the software may be implemented in an assembly language directed to the microprocessor resident on a target computer; for example, the software may be implemented in Intel 80x86 assembly language if it is configured to run on an IBM PC or PC clone. The software may be embodied on an article of manufacture including, but not limited to, a floppy disk, a jump drive, a hard disk, an optical disk, a magnetic tape, a PROM, an EPROM, EEPROM, field-programmable gate array, or CD-ROM.

In addition, the laser system may incorporate one or more systems for detecting the thickness of the workpiece and/or heights of features thereon. For example, the laser system may incorporate systems (or components thereof) for interferometric depth measurement of the workpiece, as detailed in U.S. patent application Ser. No. 14/676,070, filed on Apr. 1, 2015, the entire disclosure of which is incorporated by reference herein. Such depth or thickness information may be utilized by the controller to control the output beam to optimize the processing (e.g., cutting, piercing, or welding) of the workpiece, e.g., in accordance with records in the database corresponding to the type of material being processed.

The terms and expressions employed herein are used as terms of description and not of limitation, and there is no intention, in the use of such terms and expressions, of excluding any equivalents of the features shown and described or portions thereof, but it is recognized that various modifications are possible within the scope of the invention claimed.

1. A laser apparatus comprising:
a plurality of single-beam emitters each configured to emit only a single beam, wherein the emitters are arranged to partially surround a central axis and positioned to each emit its beam to the central axis; and
disposed at the central axis, a plurality of interleaving mirrors, wherein each of the interleaving mirrors is configured to receive the beam from a different emitter and direct the beam to a shared exit point, whereby a beam stack is output at the shared exit point,
wherein the emitters are positioned such that optical distances traversed by each beam from its emitter to the shared exit point are all equal to each other.

2. The apparatus of claim 1, wherein each emitter comprises a diode emitter.

3. The apparatus of claim 1, further comprising a plurality of fast-axis collimation (FAC) lenses, each FAC lens being positioned to receive the beam from a different emitter and collimate the beam in the fast axis.

4. The apparatus of claim 1, further comprising a slow-axis collimation (SAC) lens disposed at the shared exit point and configured to receive, and collimate in the slow axis, the beam stack.

5. The apparatus of claim 1, wherein, when viewed in plan view, the emitters are arranged in one or more circular arcs disposed around the central axis.

6. The apparatus of claim 5, wherein, within each circular arc, the emitters are positioned to form a single spiral staircase in which vertical heights of adjacent emitters increase along a length of the spiral staircase.

7. The apparatus of claim 5, wherein (i) the one or more circular arcs comprise a first circular arc and a second circular arc, and (ii) vertical heights of emitters within the second circular arc are all higher than vertical heights of emitters within the first circular arc.

8. The apparatus of claim 5, wherein (i) the one or more circular arcs comprise a first circular arc and a second circular arc, and (ii) the emitters within the first circular arc are vertically interleaved with the emitters within the second circular arc, whereby vertical heights of some emitters within the first circular arc are higher than vertical heights of some emitters within the second circular arc, and vice versa.

9. The apparatus of claim 1, wherein the emitters are positioned such that, when viewed in plan view, none of the positions of any of the emitters overlap with each other.

10. The apparatus of claim 1, wherein the emitters are positioned such that, when viewed in plan view, positions of at least two of the emitters overlap with each other.

11. The apparatus of claim 1, wherein each of the emitters is disposed at a different vertical position.

12. The apparatus of claim 1, further comprising an additional emitter positioned to emit a beam through the central axis directly to the shared exit point without being received by an interleaving mirror, wherein the beam stack comprises the beam of the additional emitter.

13. The apparatus of claim 12, wherein the additional emitter is disposed at a vertical height different from vertical heights of all of the emitters.

14. The apparatus of claim 12, wherein the additional emitter is disposed at a vertical height higher than vertical heights of all of the emitters.

15. The apparatus of claim 1, further comprising a base mount defining a plurality of flat platforms, each emitter being disposed on a different platform.

16. The apparatus of claim 15, wherein the base mount defines therein a plurality of cooling channels configured to accommodate cooling fluid.

17. The apparatus of claim 15, wherein each of the flat platforms is disposed at a different vertical height.

18. The apparatus of claim 15, wherein the base mount defines an opening configured to accommodate, and transmit therethrough, the beam stack at the shared exit point.

19. The apparatus of claim 1, wherein at least two of the interleaving mirrors have different widths.

20. The apparatus of claim 1, wherein widths of all of the interleaving mirrors are equal to each other.

21.-56. (canceled)
